(19) United States
(12) Patent Application Publication
(10) Pub. No.: US 2006/0049337 A1
(43) Pub. Date: Mar. 9, 2006

(54) Optoelectronic sensor

(76) Inventor: Martin Waeny, Funchal (PT)

Correspondence Address: TAROLLI, SUNDHEIM, COVELL & TUMMINO L.L.P., 526 SUPERIOR AVENUE, SUITE 1111, CLEVEVLAND, OH, 44114, US

(21) Appl. No.: 10/491,999

(22) PCT Filed: Oct. 9, 2001
(86) PCT No.: PCT/EP01/11673

§ 371 Date: Jul. 29, 2005

(51) Int. Cl. H01J 40/14; H03F 3/08

(52) U.S. Cl. 250/214 R

(57) ABSTRACT

The present invention proposes a photodetector comprising a zone (2) of semiconductor material suitably doped voltage (4) and a sensing node (16), wherein the sensing node (16) is connected to a voltage sensing circuit comprising a capacitance (8) at its entrance, wherein means (9) are provided to deconnect the sensing node (16) from the voltage sensing circuit such as to temporarily sample and hold a voltage signal on said capacitance (8) of the voltage sensing circuit, and wherein that said capacitance (8) is connected to a non-linear voltage transconductance element suitable to prevent saturation of the voltage sensing circuit.

### FIELD OF THE INVENTION

The invention relates to an optoelectronic sensor, a line sensor or image sensor composed of such sensors and generally a method for detecting light according to the preambles of the independent claims.

### BACKGROUND OF THE INVENTION

To date area (2-dimensional) image sensors in CMOS Technology (Complementary Metal Oxyde Semiconductor) are widely used in applications where images with a large variation of the optical intensity of the impinging light (high dynamic imaging) have to be acquired. If an image has to be acquired of a fast moving scene, all image points have to be exposed at the same time to prevent motion distortion of the image. Since the image data of the sensor in CMOS technology typically has to be read out sequentially, the image data has to be stored locally, close to the photo detector of the pixel, before it can be read out. Such local storage never is perfect, and the stored signal can still be influenced by the optical signal impinging on the detector after the desired exposure time (post exposure). This can lead to loss of data, especially in the case where an extremely short exposure time, compared to the readout time, is desired to prevent saturation of the signal in the acquisition of a scene with very bright illumination. In this case the post exposure may lead to the saturation of the detector output, especially for the data read out last.

### SUMMARY OF THE INVENTION

It is therefore the aim of the invention to provide a photodetector with the possibility to store image information locally in the detector array, at the same time preventing the loss of data due to saturation created by post exposure.

This aim is achieved by a photodetector as described in claim 1, that is by a photodetector comprising a zone of semiconductor material suitably doped to collect photogenerated charges, coupled between a ground voltage and a sensing node, wherein the sensing node is connected to a voltage sensing circuit comprising a capacitance at its entrance, wherein means are provided to deconnect the sensing node from the voltage sensing circuit such as to temporarily sample and hold a voltage signal on said capacitance of the voltage sensing circuit, and

wherein that said capacitance is connected to a non-linear voltage transconductance element suitable to prevent saturation of the voltage sensing circuit.

The key of the present invention is therefore that a non-linear voltage transconductance element, which is connected to the capacitance at the entrance of the voltage sensing circuit, provides the possibility of influencing the voltage measured across said capacitance after the exposure/integration time of the detector such that distortions of the measured voltage due to post-exposure effects do not lead to a loss/confusion of the actual information and acquired during the exposure time. The non-linear voltage transconductance element thereby leads to a non-linear behaviour of the voltage across said capacitance at the entrance of the voltage sensing circuit, which non-linearity has the effect that the measured voltage never drops below a saturation level thereby avoiding confusion of different initial values of the voltage.

According to a preferred embodiment of the present invention the photodetector additionally comprises a capacitance which is coupled in parallel to the zone of semiconductor material, between the ground voltage and the sensing node.

According to another preferred embodiment the photodetector is characterised in that zone of semiconductor material suitably doped to collect photogenerated charges is a photodiode and in that the sensing node of this photodiode is connected or deconnected from the voltage sensing circuit by means of a transistor, preferably by means of a MOS transistor.

Another preferred embodiment is characterised in that the non-linear voltage transconductance element is realised by a transistor, preferably by a MOS transistor, which has its gate connected to a suitable potential. It is then preferably possible to connect the gate of the transistor to its source. It is also possible to connect the gate of the transistor to an externally controlled signal. This externally controlled signal may additionally be changed over time.

Concerning the non-linear voltage transconductance element this may either be realised by a transistor or by a diode, which has its other terminal connected to a suitable potential, fixed or variable over the time.

The photodetector may then be characterised in that the a zone of semiconductor material suitably doped to collect photogenerated charges, preferably the photodiode, generates a non-linear response to the impinging light intensity.

According to another preferred embodiment of the present invention, the non-linear element is used to reset the storage node or the storage node and the diode.

Further preferred embodiments of the present invention are described in the claims depending on the main claim.

Additionally the present invention concerns a 1- or 2-dimensional array, preferably in the form of a line sensor or an image sensor, at least partially composed of photodetectors as described above.

### DESCRIPTION OF THE INVENTION

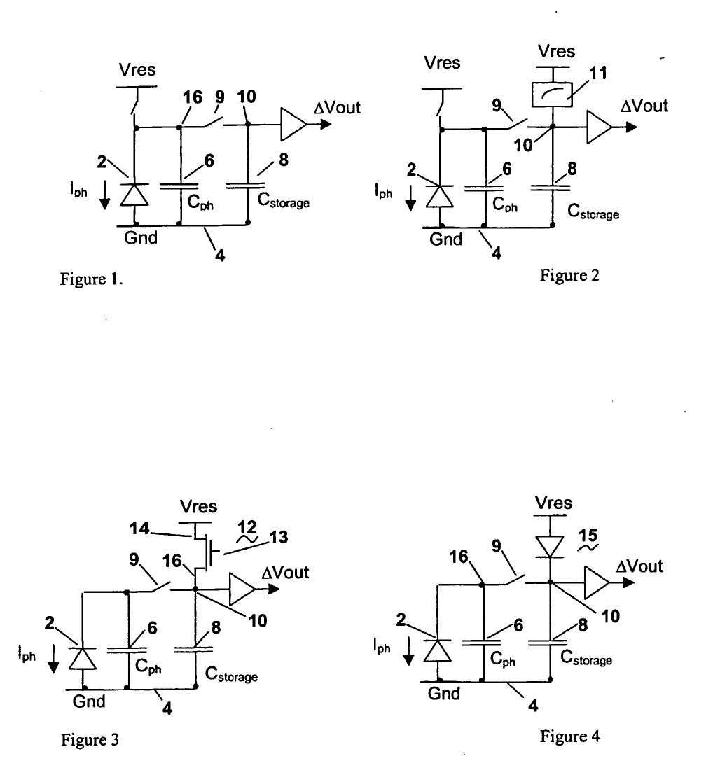

In a classical CMOS image sensor for each image point a photodetector, typically a photodiode 2, is connected to a sensing circuit (see FIG. 1). In order to store the signal of the photodetector after exposure until the image point is read out, the photodetector is deconnected by means of a switch 9 (M1), typically a MOS transistor, from the readout circuit. If the detector 2 is deconnected, its output voltage is stored on the parasitic capacitance 8 associated with the readout circuitry (storage node 10). Typically the storage node 10 is covered by light shields to prevent post exposure. Though light shielding available in standard processing technologies does not completely obscure the storage node. Additionally the signal of the detector can still influence the voltage value on the storage node 10 due to imperfect switching behaviour and charge generation outside the actual photodetector area 2. Though, if for a time long compared to the exposure time a signal value shall be stored on the storage node 10 and when the sensor 2 is exposed to high optical intensities, the voltage on the storage node 10 is likely to exceed or drop below the entrance level of the voltage sensing circuit and thus risks to saturate.

All descriptions given here refer, when indicated to N-MOS devices, though the invention works likewise for P-MOS devices which can easily been understood by the skilled, reader.

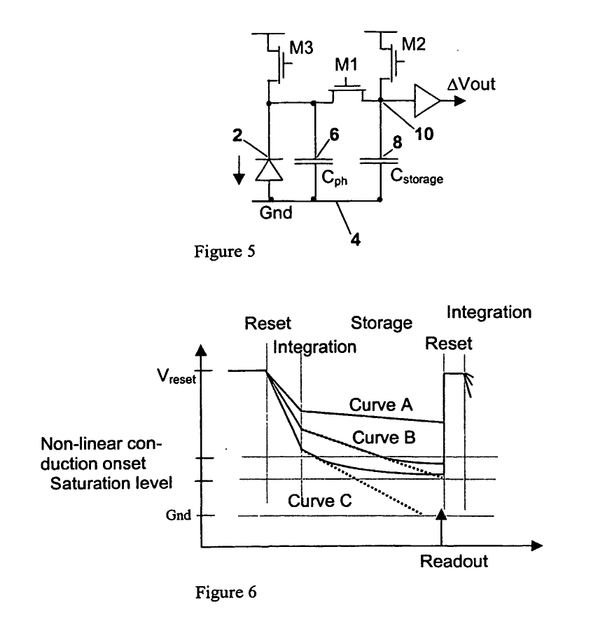

In order to prevent the saturation of the storage node even under extreme illumination conditions and for long storage times, the sensor according to the invention consists of a non-linear response element 11 connected to the storage node 10 (see FIG. 2). Preferably this non-linear element 11 is a MOS transistor 12 with its gate 13 connected to a potential V_{control}, which is fixed or controlled externally (see FIG. 3). Alternatively the non-linear element might be a simple diode 15 (see FIG. 4), or any other non-linear circuit, working similar to the described principle. See FIG. 5 for the preferred embodiment, where a separate MOS is connected to the photodiode 2 to fix the photodiode potential to the reset potential immediately after the exposure in order to minimise the effect of the photodiode 2 to the storage node 10. This MOS transistor M3 can further be used to generate a non-linear compression of the photodiode response. See WO 01/46655 for more detail, the full content of this document WO 01/46655 is explicitely included into this disclosure as concerns the particular use of transistor M3 to make the response on the sensing node 16 non-linear in particular regimes and particularly the combination of the disclosure in WO 01/46655 concerning M3 with the means proposed in this document (11, 12, M2) shall be included.

During exposure the photodetector 2 is connected by means of the MOS-transistor M1 to the storage node 10. Depending on the impinging light intensity, the potential of the photodetector 2 and the storage node 10 is deviated from its initial level. After completion of the integration the storage node 10 is disconnected from the photodiode 2 by means of applying a potential to the gate of the MOS-transistor M1 such as to block this transistor. The final signal value is now stored on the parasitic capacitance 8 of the storage node 10 C_{Storage}. During the storage time, the sum of the currents generated by leakage of the switch M1 and generated through illumination through the light shielding deviates the potential of the storage node 10 from its initial value. Formula 1 describes the Voltage on the storage node 10, as a function of the post exposure current (I_{Leak}+I_{Shield}) and the storage time. V_{Exposure} stands for the potential of the storage node 10 immediately after the storage node 10 is disconnected from the photodetector 2.

$${V}_{Store} = \frac{{T}_{Store} \cdot ( {I}_{Leak} + {I}_{Shield} )}{{C}_{Storage}} + {V}_{Exposure} \qquad Formula 1$$

In a first time, the storage node 10 deviates linearly with increasing time from the initial level, and linearly with the sum of the post exposure currents Iₗₑₐₖ and I_{Shield}. Initially the non-linear circuit 11, 12,15 connected to the storage node 10 is configured such as not to conduct any current. Preferably the non-linear circuit is realised by a MOS-transistor 12, with its gate 13 connected to a voltage between the voltage level of the unexposed sensor (Vᵣₑₛ) plus 1 threshold voltage (V_{TH}, i.e. V_{ref}+V_{TH}) and the saturation voltage (Vₛₐₜ) of the sensing circuit plus 1 threshold voltage (V_{TH}, i.e. Vₛₐₜ+V_{TH}). Initially the non-linear circuit (MOS transistor M2) does not pass any current. Once the storage node 10 voltage reaches a value, 1 VTH below the gate voltage level of M2, the transistor starts to conduct. From that moment on, the storage node voltage is no longer defined by Formula 1, but by the current voltage function of the non-linear circuit. In the preferred embodiment by the gate source voltage of the MOS transistor M2. The gate source voltage, and thus the voltage on the storage node 10 is described by formula 2. Typically the post exposure photocurrent and the leakage current are in the order of femtoamperes to nanoamperes. Thus the MOS transistor M2 operates in weak inversion mode.

$${V}_{GS} = \frac{kT}{κ q} ln ( \frac{{I}_{Leak} + {I}_{Shield}}{{I}_{0}} ) + {V}_{TH} \qquad Formula 2$$

κ is a process dependent transistor parameter, I₀ is the drain current at the onset of the weak inversion operation and V_{TH} is the transistor threshold voltage. kT/q is roughly 26 mV at ambient temperature.

Once the storage node potential reaches values where the non-linear element is conducting current, the final value which is read out does not only depend on the signal after exposure, but on the integrated post exposure current and the actual post exposure current at read-out. Due to the dependence of the voltage across the linear element to the post exposure current, which itself is a function of the impinging light intensity, the storage node potential does not saturate completely but stays related to the impinging light intensity. FIG. 6 shows the voltage of the storage node as a function of time for three different intensities of impinging light. At a relatively low intensity of the impinging light the storage node does not enter a mode where the non-linear element is conducting. (Curve A). At a higher optical intensity, the storage node potential decreases fast enough to enter a mode where the non-linear element becomes conductive. The final storage node potential is a function of the post-exposure current (Curve B). At an even higher optical intensity, the storage node potential decreases very fast to values where the non-linear element is conducting. Due to the more important post exposure current, the voltage across the non-linear element is more important than for a smaller optical intensity (Curve C) Therefore the two intensities related to Curve B and C are not confused at read-out, which would be the case without the non-linear element. See dotted lines for the behaviour of the storage node voltage without non-linear element). Curve B and C reach the saturation level Vₛₐₜ of the voltage sensing current and thus would be confused, which leads to a loss of data.

List of Reference Numerals

2 photodiode
4 ground voltage line
6 photodiode capacitor
8 storage capacitor
9 storage switch
10 storage node
11 non-linear response element
12 MOS transistor
13 gate
14 drain
15 diode 16 source

1. A photodetector comprising:
a zone (2) of semiconductor material suitably doped to collect photogenerated charges, coupled between a ground voltage (4) and a sensing node (16),
wherein the sensing node (16) is connected to a voltage sensing circuit comprising a capacitance (8) or a parasitic capacitance (8) at its entrance,
wherein means (9) are provided to deconnect the sensing node (16) from the voltage sensing circuit such as to temporarily sample and hold a voltage signal on said capacitance (8) of the voltage sensing circuit, and
wherein that said capacitance (8) is connected to a non-linear voltage transconductance element suitable to prevent saturation of the voltage sensing circuit.

2. A photodetector according to claim 1, characterized in that a capacitance (6) is coupled in parallel to the zone of semiconductor material, between the ground voltage (4) and the sensing node (16).

3. A photodetector according to claim 1, characterized in that the zone of semiconductor material suitably doped to collect photogenerated charges is a photodiode (2) and in that the sensing node (16) of this photodiode (2) is connected or deconnected from the voltage sensing circuit by means of a transistor (M1), preferably by means of a MOS transistor.

4. A photodetector according to claim 1, characterized in that the non-linear voltage transconductance element (11) is realized by a transistor (12, M2), preferably by a MOS transistor, which has its gate (13) connected to a suitable potential.

5. A photodetector according to claim 1, characterized in that the gate (13) of the transistor (12, M2) is connected to its source (16) or its drain (14).

6. A photodetector according to claim 1, characterized in that the gate (13) of the transistor (12, M2) is connected to an externally controlled signal.

7. A photodetector according to, claim 1, characterized in that the gate (13) of the transistor (12, M2) is connected to an externally controlled signal which is changed over the time.

8. A photodetector according to claim 1, characterized in that the non-linear voltage transconductance element (11) is realized by a diode (15), which has it other terminal connected to a suitable potential, fixed or variable over the time.

9. A photodetector according to claim 1, characterized in that the zone (2) of semiconductor material suitably doped to collect photogenerated charges, preferably the photodiode (2), in combination with another non-linear circuit or element (M3) generates a non-linear response to the impinging light intensity.

10. A photodetector according to claim 1, characterized in that the non-linear element (11) is used to reset the storage node (10) or the storage node and the diode (15).

11. 1- or 2-dimensional array, preferably in the form of a line sensor or an image sensor, at least partially composed of photodetectors according to claim 1.
